(19) United States
(12) Patent Application Publication
(10) Pub. No.: US 2024/0393918 A1
(43) Pub. Date: Nov. 28, 2024

(54) USER INTERFACE FOR A TENSOR BUILDER TO CONSTRUCT IMAGES FOR INPUT TO MACHINE LEARNING

(71) Applicant: Tektronix, Inc., Beaverton, OR (US)

(72) Inventors: John J. Pickerd, Hillsboro, OR (US); Kan Tan, Portland, OR (US); Wenzheng Sun, Beaverton, OR (US)

(21) Appl. No.: 18/665,258

(22) Filed: May 15, 2024

Related U.S. Application Data
(60) Provisional application No. 63/468,779, filed on May 24, 2023.

(51) Int. Cl. G06F 3/0482; G06F 3/0484

(52) U.S. Cl. CPC G06F 3/0482; G06F 3/0484

(57) ABSTRACT

A test and measurement instrument includes one or more ports to allow the test and measurement instrument to receive data from a device under test (DUT), a connection to a machine learning network, a display configured to display a user interface, one or more controls to allow the test and measurement instrument to receive inputs from a user, and one or more processors configured to execute code that causes the one or more processors to: render a menu on the display that displays different types of tensors, receive, from the one or more controls, a user selection that identifies a selected type of tensor, and build the selected type of tensor from the data from the DUT and send the selected type of tensor to the machine learning network. A method of providing a user interface is also disclosed.

### CROSS-REFERENCE TO RELATED APPLICATIONS

This disclosure is a non-provisional of and claims benefit from U.S. Provisional Application No. 63/468,779, titled “USER INTERFACE FOR A TENSOR BUILDER TO CONSTRUCT IMAGES FOR INPUT TO MACHINE LEARNING,” filed on May 24, 2023, the disclosure of which is incorporated herein by reference in its entirety.

### TECHNICAL FIELD

This disclosure relates to test and measurement systems and methods, and more particularly to applying machine learning to measurements of a signal from a device under test.

### DESCRIPTION

U.S. patent application Ser. No. 17/747,954, filed May 18, 2022, titled “SHORT PATTERN WAVEFORM DATABASE BASED MACHINE LEARNING FOR MEASUREMENT,” hereinafter “the '954 application,” the contents of which are hereby incorporated by reference into this application, describes systems and methods for applying a trained machine learning system to make predictions of measurements for signals received from a device under test (DUT). One example signal measurement is Transmitter and Dispersion Eye Closure Quaternary (TDECQ) when the DUT is, for example, an optical transceiver. Input to the machine learning systems described in the '954 application, both for training and runtime, is in the form of tensor images that are built using graphical representations of particular short pattern segments within long waveforms acquired from DUTs.

U.S. patent application Ser. No. 17/701,186, filed Mar. 24, 2022, titled “OPTICAL TRANSMITTER TUNING USING MACHINE LEARNING AND REFERENCE PARAMETERS,” hereinafter “the '186 application,” the contents of which are hereby incorporated by reference into this application, describes applying a trained machine learning system to make a prediction of optimal tuning parameters for an optical transceiver DUT.

U.S. patent application Ser. No. 18/199,846, filed May 19, 2023, titled “AUTOMATED CAVITY FILTER TUNING USING MACHINE LEARNING,” hereinafter “the '846 application,” the contents of which are hereby incorporated by reference into this application, describes systems and methods for applying a trained machine learning system for making predictions of optimal positions of tuning elements in a tunable device under test, such as a cavity filter. Input to the machine learning systems described in the '846 application, both for training and runtime, is in the form of tensor images that are built using graphical representations of scattering parameters (S-parameters) or other parameters that characterize DUTs.

Tensors represent a way to efficiently provide information to a machine learning system for either training or operation. U.S. patent application Ser. No. 18/510,234, “METHOD FOR THREE-DIMENSIONAL TENSOR BUILDER FOR INPUT TO MACHINE LEARNING,” hereinafter “the '234 application,” the contents of which are hereby incorporated by reference into this application, describes systems and methods for creating high efficiency 3D RGB tensors that incorporates three channels of reference parameters, or S-parameters, or other types of data.

### BRIEF DESCRIPTION OF THE DRAWINGS

FIG. 1 shows an embodiment of a test and measurement device.

FIG. 2 shows an embodiment of a user interface for a tensor builder to allow a user to select a type of tensor and related parameters.

FIG. 3 shows another embodiment of a user interface for a tensor builder to allow a user to select a type of tensor and related parameters.

FIG. 4 shows another embodiment of a user interface for a tensor builder to allow a user to select a type of tensor and related parameters.

### DETAILED DESCRIPTION

According to embodiments of this disclosure, numerous applications may be built using waveforms or S-parameters as input data to a deep learning network in a machine learning application. Embodiments of this disclosure generally include user interfaces and methods for building tensor images for input to a deep learning network for making predictions in test and measurement applications.

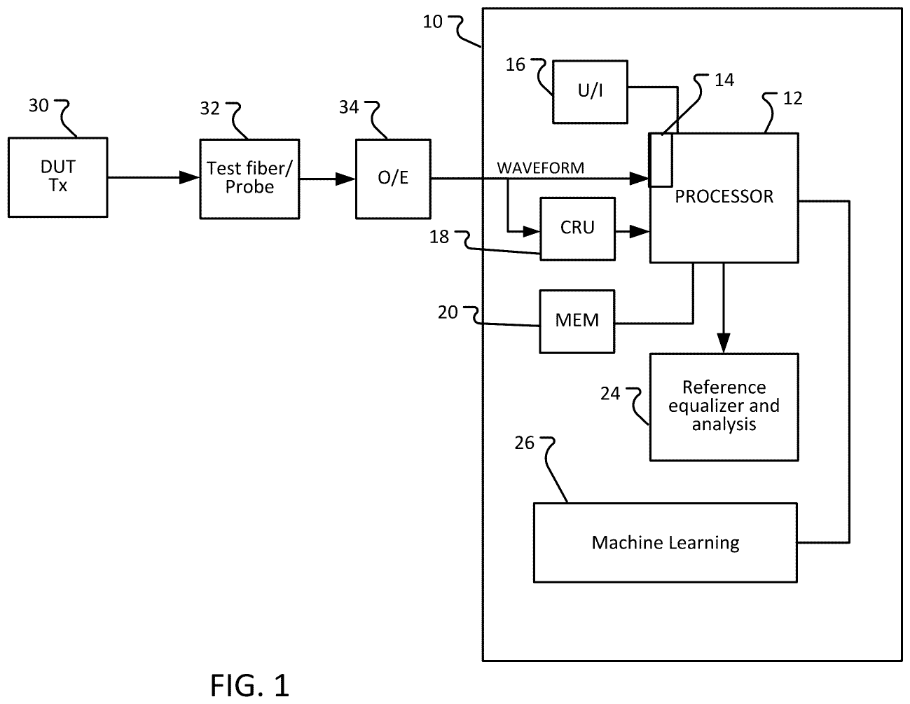

FIG. 1 shows an embodiment of a test and measurement device that provides one or more user interfaces. The embodiments may involve a test and measurement instrument having one or more processors executing code that causes the processors to perform the various tasks. The machine learning system may take the form of programmed models operating on one or more of the processors. FIG. 1 shows an embodiment of a testing setup in the instance of an optical transmitter 30 as a device under test (DUT). The testing setup includes a test and measurement system that may include a test and measurement instrument such as an oscilloscope 10. The test and measurement instrument 10 receives a signal from the DUT 30 through an instrument probe 32. In the case of an optical transmitter, the probe will typically comprise a test fiber coupled to an optical to electrical converter 34 that provides a signal to the test and measurement instrument through one or more ports 14. Two ports may be used for differential signaling, while one port is used for single-ended channel signaling. The signals are sampled and digitized by the instrument to become waveforms. A clock recovery unit (CRU) 18 may recover the clock signal from the data signal if the test and measurement instrument 10 comprises a sampling oscilloscope for example. A software clock recovery can be used on a real-time oscilloscope.

The test and measurement instrument has one or more processors represented by processor 12, a memory 20, and a user interface 16. The memory may store executable instructions in the form of code that, when executed by the processor, causes the processor to perform tasks. User interface 16 of the test and measurement instrument allows a user to interact with the instrument 10, such as to input settings, configure tests, etc. The test and measurement instrument may also include a reference equalizer and analysis module 24. User interface 16 may comprise a display and one or more controls to allow the user to configure the device. The controls may comprise one or more switches, knobs, or other forms of input, or may comprise touch buttons on the display.

The embodiments here employ machine learning in the form of a machine learning network 26, such as a deep learning network. The machine learning network may include a processor that has been programmed with the machine learning network as either part of the test and measurement instrument, or to which the test and measurement instrument has access through a connection. As test equipment capabilities and processors evolve, one or more processors such as 12 may include both.

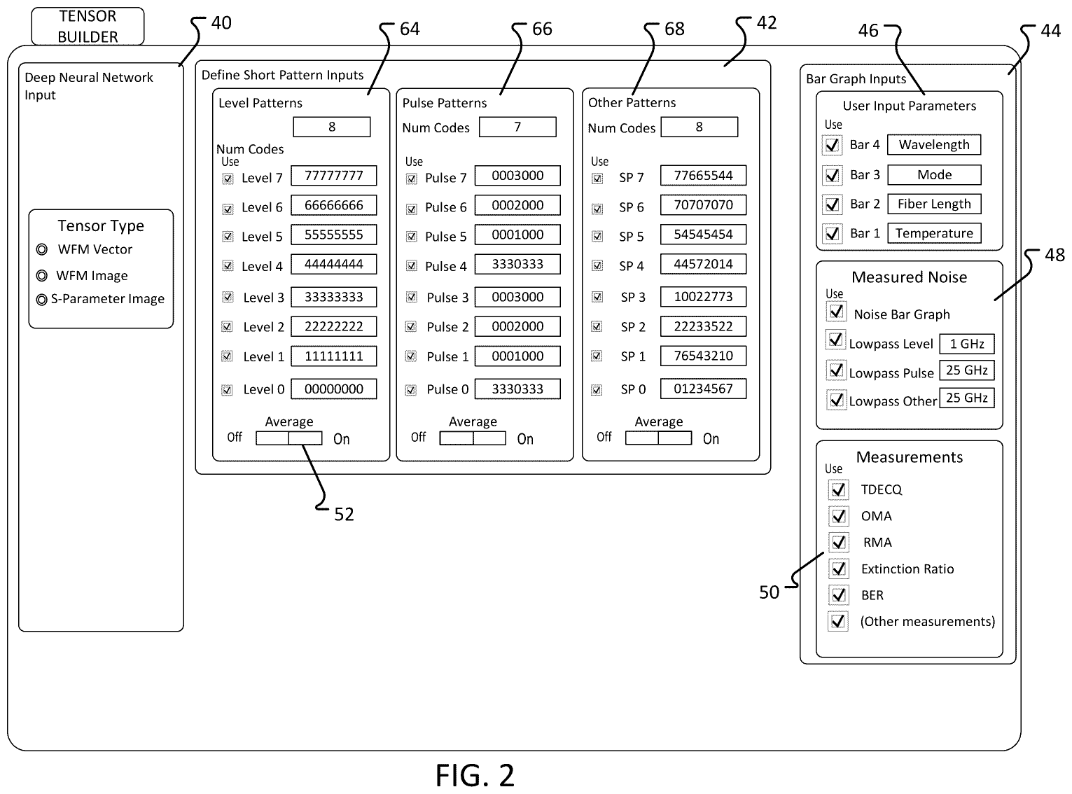

FIG. 2 shows one embodiment of a user interface according to some embodiments of the disclosure. One or more processors would render the user interface on the display. The user interface presents a deep neural network input panel 40 that allows the user to pick from different selections for types of tensors. As shown here, the types comprise a waveform (WFM) vector, a WFM image, and an S-parameter image. The user interface menu allows the user to make selections to create a waveform vector to use as input to the deep learning neural networks in the application. In the particular example of FIG. 2, the user has selected a WFM vector, so the other tabs displayed comprise define short pattern inputs panel 42 to allow the user to define the short pattern inputs. As used here, the term “short pattern” comprises short pattern waveform segments, as set out in the '954 application referenced above.

This tensor comprises a one-dimensional waveform data vector. However, multiple user defined short pattern waveform sequences concatenated together make up the one-dimensional waveform data vector. The user interface also provides an average switch 52 where all like short patterns found in the waveform may be averaged together before concatenating them together.

Bar graph inputs panel 44 allows the user to transform bar graphs into waveform segments and concatenate them into the waveform data tensor vector. The panel 44 includes panels 46, 48, and 50. User input parameters panel 46 provides options for user defined input parameters that may apply to the particular test and measurement application such as temperature, or fiber length, or any other desired parameters. The noise bar graph selections panel 48 governs creation of a noise bar graph created by performing a noise measurement on the waveform. The user has the option to control lowpass filtering on each defined group of short patterns. The user may also select one of the measurements, such as those shown in measurements panel 50, used to create the bar graphs. The measurement options may vary from those shown as examples.

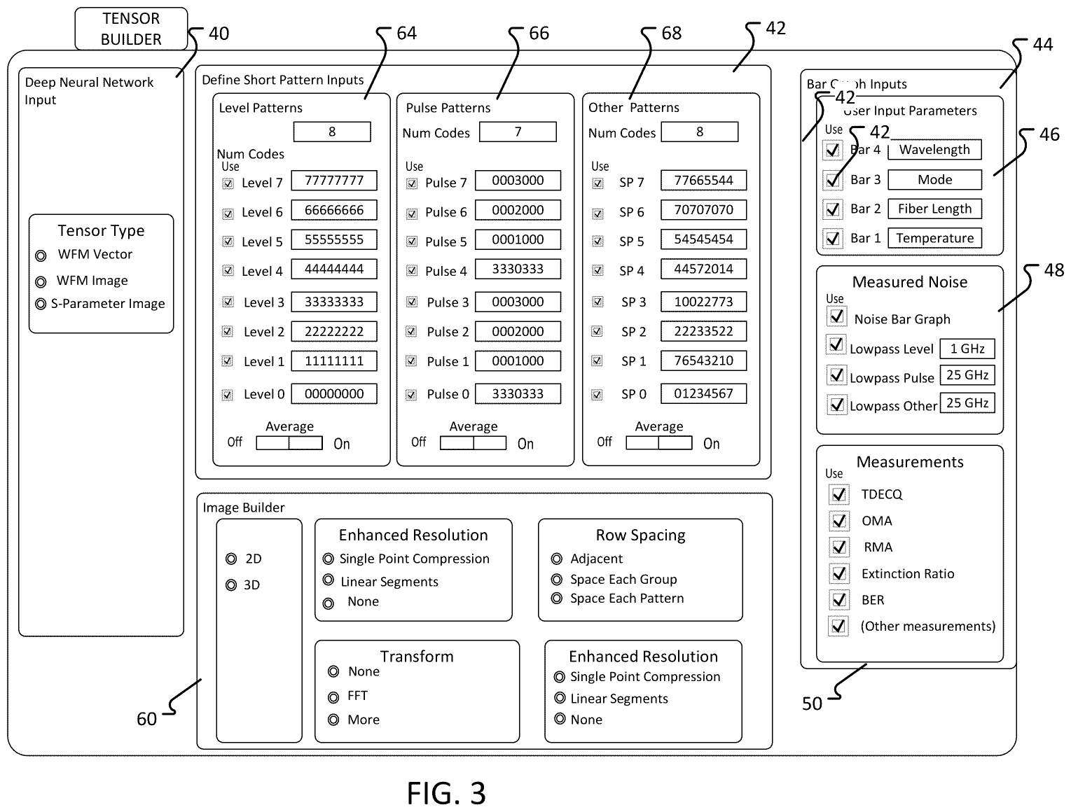

FIG. 3 illustrates the user interface when the user selects the tensor type as a WFM image to create a waveform image to use as input to the deep learning neural networks in the application. The user interface in this situation includes an image builder panel 60. The user can select from either two-dimensional or three-dimensional waveform images. In a first embodiment, the tensor comprises a two-dimensional waveform data image where the Z-axis contains histogram data of how many counts each point has occurred in the waveform short patterns. In a second embodiment, the user may also select the image as a 3D image where the Z-axis represents the amplitude of each waveform, and many more waveforms can fit into many rows of the XY plane. This makes the image more efficient and able to handle more data. All of the user defined short pattern waveform segments can fit into the image.

Bar graphs may also be created as explained above and incorporated into the tensor image.

The tensor image may be RGB with different waveforms into each channel. Placement of which waveform goes into which color channel is controlled behind the scenes in the application. However, additional menu controls can be added to specify what data goes into what color channel.

Another feature is that bar graphs may be transformed into waveform segments and concatenated into the waveform data tensor vector using bar graph user inputs panel 44, also shown in FIG. 2. The bar graphs may be created based on user defined input parameters such as temperature, or fiber length or any other desired parameters as shown in panel 46, also shown in FIG. 2. The user may choose to include a noise bar graph by designating a noise measurement on the waveform as shown in panel 48. The user has the option to control lowpass filtering on each group of short patterns that are defined. The bar graphs may also be created from a list of user selected measurements that exist with the particular application containing this tensor builder menu as shown in panel 50.

This interface includes image builder panel 60 that is used to control various ways for creating the organization of the data going into the image tensor. Additional menu controls may also exist, the ones shown merely provide examples. Through this user interface, the user has control over how the test and measurement instrument organizes the data inside the waveform image.

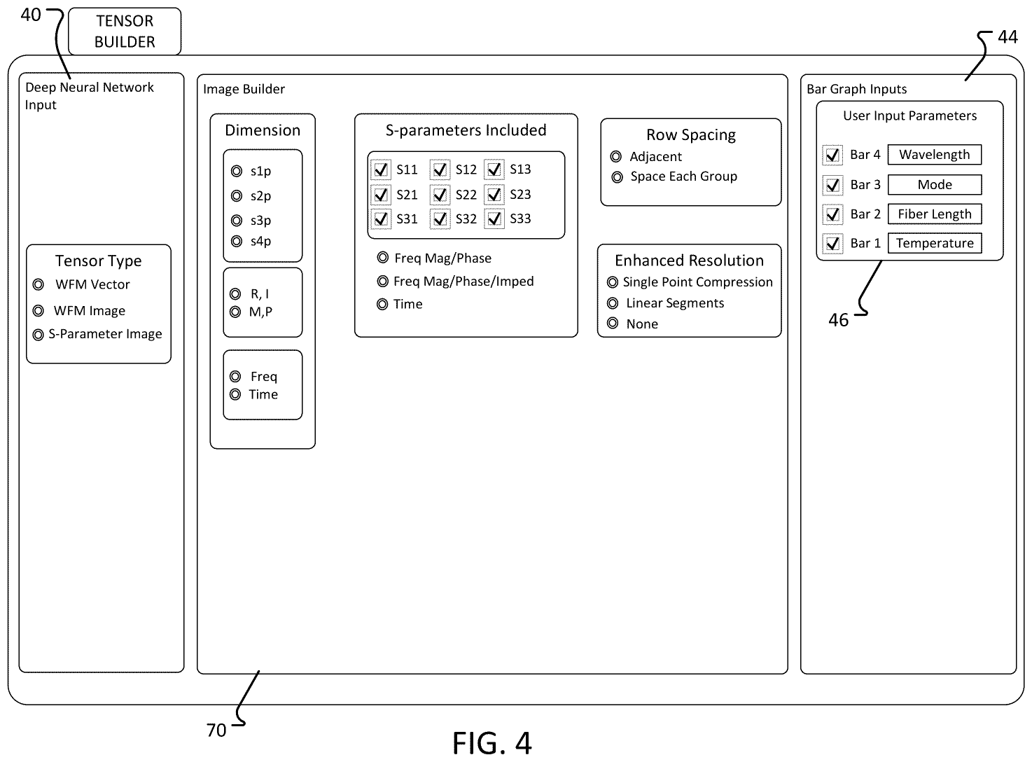

FIG. 4 shows an embodiment of the tensor builder menu when the user has selected to create an S-parameter image as input to the deep learning neural networks. This tensor comprises a three-dimensional S-parameter data image where the XY images comprise real or imaginary parts or magnitude and phase parts. Each row in the XY image represents either real, or imaginary, or magnitude, or phase, of one of the S-parameters in the set. Bar graphs may also be created as explained above and incorporated into the tensor image.

The tensor image may comprise RGB image with three different reference S-parameter results from a measured DUT going into one of the RGB color channels. However, the instrument may allow the user to view the RGB image tensor animations. They do see the image tensors and how they are organized. The user interface also displays the bar graph input panel 46 in the bar graph user inputs panel 44 to allow the user to designate bar graphs for transformation from either measurements, or user defined input parameters such as temperature, or other. The measured noise panels 48 and the measurements panel 50 shown in FIGS. 2 and 3 are not used for the S-parameter tensor builder.

The S-parameter interface includes an Image Builder menu panel 70 that is used to control various ways for creating the organization of the data going into the S-parameter image tensor. The user interface may employ additional menu controls other than those shown below.

The below discussion provides more detailed descriptions of the elements of the user interfaces above. As discussed above, the tensor builder menu tab comprises the highest-level menu in embodiments here and contains all the other menu items needed to build either a waveform vector, or a waveform image, or an S-parameter image to use as input to the deep learning neural networks of the application. It may include one or more of the following menu items.

The Deep Neural Network Input panel 40 has three choices for types of tensor data input to the neural networks. The user interface does not present the algorithms for creating these tensors to the user of this application. These include WFM Vector that enables creation of a 1D waveform vector containing many short pattern waveform segments where a large amount of the waveform has been discarded and only keeps the portions significant to training the network. The vector may also contain bar graphs containing input parameters converted to waveform segments representing the bar graph. Another option includes WFM Image that specifies that the instrument will create a 2D or 3D image tensor to contain the bar graphs and the multiple short pattern waveform data segments. The images may be monochrome or RGB. The last selection provided here comprises an S-parameter Image. This option takes in S-parameters obtained from a device under test (DUT) and builds them into an RGB or monochrome image to use as input to the neural networks. The image may also use other parameters such as S-parameters in the time domain, Z-parameters (open circuit or impedance parameters), H-parameters (hybrid parameters), X-parameters (generalization of S-parameters), and many others.

The Define Short Pattern Inputs panel 42 for the waveform images shown in FIGS. 2 and 3 allows the user to define the code sequence of each short pattern waveform segment that is to be included in the image tensor. There are three groups of pattern types. There are up to 8 short patterns that may be used in each group. This supports NRZ to PAM3, PAM4, and all the way up to PAM8 type of signals. The number representing the number of PAM levels defines the signal level of the signal for each unit interval. Levels for NRZ would be 0 and 1. Levels for PAM3 would be 0, 1, and 2, etc. The Level Patterns panel 64 comprise consecutive number of unit intervals where signal levels stay at the same level for each unit interval in the sequence. However, the user may, if desired, define any kind of pattern sequence in this menu tab. The Pulse Patterns panel 66 definitions are intended to be sequences of all one level with one of the unit intervals set to a different level to create a pulse pattern. The user may define up to 8 different pulse patterns, and whether or not to enable each one to go into the tensor image. The Other Patterns menu panel 68 allows for the definition of up to 8 additional short pattern waveforms to include in the tensor input data.

In these menu panels, Num Codes specifies how many unit intervals of the signal are included in the length of the short pattern. This menu item may be optional because the number of UI in each pattern could be determined separately by how many unit interval values the user entered into the edit boxes defining the short patterns. As mentioned above, the user interface includes an Average Switch such as 52 in FIG. 2. When OFF, the application will find all individual instances of all included short patterns and place them into the tensor, depending on the internal rule set for building the selected. Note not shown here, but other versions of tensor builder may have a menu for selecting additional rules for tensor building. When set to ON, all like patterns found in the waveform shall be averaged together before allowing the tensor builder to place them into the tensor according to the internal rules of the tensor builder. Some of those rules are determined by this tensor builder menu system. Some of the rules are internal to the particular end application, and some of the rules may be defined in the future by adding new menus to the tensor builder menu system.

The Image Builder menu panel in FIG. 3 only becomes visible when the user has selected either WFM Image, or S-Parameter Image in the Deep Neural Network Input menu. The Image Builder menu has different control items depending on which the user selects. When the user has selected WFM Image, one selection comprises Dimension to select a type of image. The 2D selection causes the instrument to build a 2D tensor image where the XY plane is amplitude vs time for each waveform pattern and the Z-axis is the number of sample counts from all the instances of the different patterns found in the waveform. The 3D tensor image selection increases the number of waveforms and data that can be fit into the image, and can increase the record length of patterns that fit, and can increase the vertical resolution of the data that goes in. The waveform time and amplitude of each pattern fits onto the XZ plane. Each waveform fits into a row of the XY plane of the image. These images will also be RGB with internal control of waveform data going into each color channel. This image builder menu may incorporate additional menu items to control what waveforms go into what color channels.

The Enhanced Resolution panel in panel 60 in FIG. 3 determines which enhanced vertical waveform resolution algorithm to apply when creating the waveform image. This includes Single Point Compression that controls the remapping of each individual point in the waveform with respect to min and max of all the instances of the particular short pattern the point exists in. This increases the gain of low-level signals and reduces that of high-level signals to provide better vertical resolution of low-level signals. In some embodiments, additional menu items not shown in this application would appear to control the details of the algorithm. The Linear Segments create a piecewise linear segment gain vector that is multiplied times the short pattern waveform. This algorithm is intended mainly for applying to the pulse waveforms with the intent of increasing the gain of the lower-level decayed parts of the pulse as a function of time. This results in boosting the low-level amplitude part of the pulse so that it has more resolution in the tensor image. This selection None results in no gain compression or expansion algorithm used prior to placing the short patterns into the tensor.

The Row Spacing selection determines how to space the various waveform segments across the rows of the XY image plane. The Adjacent selection results in each waveform pattern or wrapped pattern segment being placed into adjacent rows across the XY plane of the image. The Space Each Group selection causes blank rows in the XY plane being placed between each waveform pattern row, or between groups of adjacent space waveforms. For example, all instances of one pattern type would be spaced adjacent to each other. But a space of a number of empty rows will be between one short pattern group and the next short pattern group. The number of rows will be equal to the dimension of the convolution filters in the deep learning input layer.

The Space Each Pattern selection causes each pattern in the waveform to be spaced by a distance equal to dimension of convolution filter, or there may be another menu control added to determine the spacing, (not shown).

When the user selects S-parameter Image, the Image Builder 70 menu has the following contents. Dimension includes SIP: a one port S-parameter set, S2P: a two port S-parameter set, S3P: a three port S-parameter set, S4P: A four port S-parameter set. RI: use real and imaginary amplitude for each S-parameter waveform in the frequency domain, MP: Use log magnitude and phase for each S-parameter waveform in the frequency domain, Freq: represent S-parameters in the frequency domain as either real and imaginary or magnitude and phase, and Time: represent S-parameters in the time domain as amplitude vs time single waveform.

The S-Parameters Included menu panel of panel 70 allows only the desired S-parameters to be enabled for input into the tensor image. Place a check mark in the box by each S-parameter to include it into the image. Leave the box blank to exclude the S-parameter from the image. The number of check boxes and S-parameters to choose from will change depending on which selection was chosen in the Dimension menu. The Row Spacing menu determines how to space the S-parameter waveform in either the time domain or the frequency domain into the XY plane rows of the image. The Adjacent selection designates that the image will have no spacing between the individual S-parameter data vectors placed into the image rows in the XY plane of the image. The Space Each Group designates that the image will have an empty set of rows between each pair of frequency domain S-parameter waveforms. The rules for spacing will be determined by the internal algorithms. The Enhanced Resolution has the same rules as previously described to enhance vertical resolution of the S-parameter data.

The Bar Graph Inputs menu panel allows definition for various types of bar graphs to be incorporated into the tensor image. The User Input parameters 46 allow the user to define their own parameter names that are included in the metadata label for training the neural networks. This menu allows for the creation of four such user input parameters. More or less may be implemented in a final design. The Measured Noise panel 48 allows measurement of how noise is measured on the short patterns and then it transformed into a bar graph to include in the tensor. The instrument removes the noise over the spectrum as measured from the short pattern prior to placing it into the tensor. This improves the accuracy of the neural network to see the desired features in the patterns.

Another option relates to filtering in the measured noise panel 48. Applying the Lowpass Levels filter to the level waveform removes as much noise as reasonably possible. The filtered waveform is used for the creation of the levels image. The cutoff frequency may be fixed, or it may be controlled from menu or PI (Programmatic Instruction) commands. A typical cutoff frequency for this filter would be 1 GHz. The user may edit this frequency. Applying the Lowpass Pulses filter to the pulse short pattern waveform removes as much noise as reasonably possible and still maintains the primary shape of the pulse. This filtered waveform is used for the creation of the pulse image. The cutoff frequency may be fixed, or it may be controlled from menu or PI commands by the user when performing training of the neural network. The Lowpass Other filter applies to the Other patterns, and its cutoff frequency may be edited by the user.

The measurement selection panel 50 allows the user to select measurements. The instrument transforms the selected measurements into a bar graph for each one selected and then included into the tensor. Some examples of measurement are as follows, but not limited to, TDECQ OMA, RMA, Extinction Ratio, BER, and other measurements.

In summary, embodiments of the disclosure include a novel user interface menu representation for a Tensor Builder. The Tensor Builder defines how to build the input tensor data for training a neural network and for using the trained neural network in the final run time environment. Embodiments incorporate several novel features such as where the parameter bar graphs are included into the tensor. The parameters may be user defined, or measured noise, or other measurements. Furthermore, some embodiments may include parameters transformed into bar graphs represented by segments of the waveform vector. The UI allows for a choice of three types of input tensors which are waveform vector, waveform image, and S-parameters. There are multiple controls to create the short pattern waveform segments that go into the tensors, and there is an image builder menu which controls how to assemble the image tensors.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a test and measurement instrument, comprising: one or more ports to allow the test and measurement instrument to receive data from a device under test (DUT); a connection to a machine learning network; a display configured to display a user interface; one or more controls to allow the test and measurement instrument to receive inputs from a user; and one or more processors configured to execute code that causes the one or more processors to render a menu on the display that displays different types of tensors; receive, from the one or more controls, a user selection that identifies a selected type of tensor; and build the selected type of tensor from the data from the DUT and send the selected type of tensor to the machine learning network.

Example 2 is the test and measurement instrument of Example 1, wherein the data comprises one or more of waveform data and bar graph data.

Example 3 is the test and measurement instrument of either of Examples 1 or 2, wherein the code that causes the one or more processors to render the menu on the display that displays different types of tensors causes the one or more processors to display a selection between a waveform vector, a waveform image, and S-parameter image.

Example 4 is the test and measurement instrument of any of Examples 1 through 3, wherein the one or more processors are further configured to execute code to cause the one or more processors to: receive a user selection selecting a waveform vector; and render a second user interface having selections to allow the user to define short pattern inputs, bar graph inputs, measured noise, and measurements.

Example 5 is the test and measurement instrument of Example 4, wherein the code that causes the one or more processors to build the selected type of tensor from the data from the DUT causes the one or more processors to build a one-dimensional waveform vector of multiple user-defined short pattern waveform sequences concatenated together.

Example 6 is the test and measurement instrument of Example 5, wherein the code that causes the one or more processors to render a user interface causes the one or more processors to render a user interface with a selection to allow the user to average the short pattern waveform sequences prior to concatenation.

Example 7 is the test and measurement instrument of any of Examples 1 through 6, wherein the one or more processors are further configured to: receive a user selection selecting a waveform image; and render a second user interface having selections for the user to define short pattern inputs, image builder, bar graph inputs, measured noises, and measurements.

Example 8 is the test and measurement instrument of Example 7, wherein the code that causes the one or more processors to build the selected tensor comprises code that causes the one or more processors to build a two-dimensional waveform image from short pattern waveform sequences including histogram data of how many counts of each point occurs in the short pattern waveform sequences.

Example 9 is the test and measurement instrument of Example 7, wherein the code to cause the one or more processors to build the selected tensor comprises code that causes the one or more processors to build a three-dimensional image having a z-axis represents an amplitude of each waveform including in the image.

Example 10 is the test and measurement instrument of any of Examples 1 through 9, wherein the code that causes the one or more processors to build the selected type of tensor from the data from the DUT causes the one or more processors to: receive a user selection selecting a S-parameter image; and render a second user interface having selections for dimensions, image builder, and bar graph inputs.

Example 11 is the test and measurement instrument of Example 10, wherein the code that causes the one or more processors to build the selected type of tensor from the data from the DUT causes the one or more processors to build an S-parameter image having rows in an XY image, each row in the XY image representing one of either real or imaginary parts of the S-parameters, or magnitudes and phases of the S-parameters.

Example 12 is the test and measurement instrument of Example 10 wherein the code that causes the one or more processors to build the selected type of tensor from the data from the DUT causes the one or more processors to build an S-parameter image containing red-green-blue channels, and each channel has a different S-parameter.

Example 13 is a method of providing a user interface, comprising: rendering a user interface on a display of a test and measurement instrument, the user interface displaying different types of tensors; receiving, from one or more controls on the test and measurement instrument, a user selection that identifies of a selected type of tensor; building the selected type of tensor from the data from the DUT; and sending the selected type of tensor to a machine learning network.

Example 14 is the method of Example 13, wherein rendering a user interface on the display the menu on the display that displays different types of tensors comprising displaying a selection between a waveform vector, a waveform image, and S-parameter image.

Example 15 is the method of either of Examples 13 or 14, further comprising: receiving a user selection selecting a waveform vector; and rendering a second user interface having selections to allow the user to define short pattern inputs, bar graph inputs, measured noise, and measurements.

Example 16 is the method of Example 15, wherein building the selected type of tensor from the data from the DUT comprises building a one-dimensional waveform vector of multiple user defined short pattern waveform sequences concatenated together.

Example 17 is the method of any of Examples 13 through 16, further comprising: receiving a user selection selecting a waveform image; and rendering a second user interface having selections for the user to define short pattern inputs, image builder, bar graph inputs, measured noises, and measurements.

Example 18 is the method of Example 17, wherein building a two-dimensional waveform image comprises building a two-dimensional waveform image from short pattern waveform sequences including histogram data.

Example 19 is the method of any of Examples 13 through 18, further comprising: receiving a user selection selecting a S-parameter image; and rendering a second user interface having selections for dimensions, image builder, and bar graph inputs.

Example 20 is the method of Example 19, wherein building an S-parameter image comprises building an S-parameter image having rows in an XY image, each row in the XY image representing one of either real or imaginary parts of the S-parameters, or magnitudes and phases of the S-parameters.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement instrument, comprising:
one or more ports to allow the test and measurement instrument to receive data from a device under test (DUT);
a connection to a machine learning network;
a display configured to display a user interface;
one or more controls to allow the test and measurement instrument to receive inputs from a user; and
one or more processors configured to execute code that causes the one or more processors to:
render a menu on the display that displays different types of tensors;
receive, from the one or more controls, a user selection that identifies a selected type of tensor; and
build the selected type of tensor from the data from the DUT and send the selected type of tensor to the machine learning network.

2. The test and measurement instrument as claimed in claim 1, wherein the data comprises one or more of waveform data and bar graph data.

3. The test and measurement instrument as claimed in claim 1, wherein the code that causes the one or more processors to render the menu on the display that displays different types of tensors causes the one or more processors to display a selection between a waveform vector, a waveform image, and S-parameter image.

4. The test and measurement instrument as claimed in claim 1, wherein the one or more processors are further configured to execute code to cause the one or more processors to:
receive a user selection selecting a waveform vector; and
render a second user interface having selections to allow the user to define short pattern inputs, bar graph inputs, measured noise, and measurements.

5. The test and measurement instrument as claimed in claim 4, wherein the code that causes the one or more processors to build the selected type of tensor from the data from the DUT causes the one or more processors to build a one-dimensional waveform vector of multiple user-defined short pattern waveform sequences concatenated together.

6. The test and measurement instrument as claimed in claim 5, wherein the code that causes the one or more processors to render a user interface causes the one or more processors to render a user interface with a selection to allow the user to average the short pattern waveform sequences prior to concatenation.

7. The test and measurement instrument as claimed in claim 1, wherein the one or more processors are further configured to:
receive a user selection selecting a waveform image; and
render a second user interface having selections for the user to define short pattern inputs, image builder, bar graph inputs, measured noise, and measurements.

8. The test and measurement instrument as claimed in claim 7, wherein the code that causes the one or more processors to build the selected tensor comprises code that causes the one or more processors to build a two-dimensional waveform image from short pattern waveform sequences including histogram data of how many counts of each point occurs in the short pattern waveform sequences.

9. The test and measurement instrument as claimed in claim 7, wherein the code to cause the one or more processors to build the selected tensor comprises code that causes the one or more processors to build a three-dimensional image having a z-axis represents an amplitude of each waveform including in the image.

10. The test and measurement instrument as claimed in claim 1, wherein the code that causes the one or more processors to build the selected type of tensor from the data from the DUT causes the one or more processors to:
receive a user selection selecting a S-parameter image; and
render a second user interface having selections for dimensions, image builder, and bar graph inputs.

11. The test and measurement instrument as claimed in claim 10, wherein the code that causes the one or more processors to build the selected type of tensor from the data from the DUT causes the one or more processors to build an S-parameter image having rows in an XY image, each row in the XY image representing one of either real or imaginary parts of the S-parameters, or magnitudes and phases of the S-parameters.

12. The test and measurement instrument as claimed in claim 10 wherein the code that causes the one or more processors to build the selected type of tensor from the data from the DUT causes the one or more processors to build an S-parameter image containing red-green-blue channels, and each channel has a different S-parameter.

13. A method of providing a user interface, comprising:
rendering a user interface on a display of a test and measurement instrument, the user interface displaying different types of tensors;
receiving, from one or more controls on the test and measurement instrument, a user selection that identifies of a selected type of tensor;
building the selected type of tensor from the data from the DUT; and
sending the selected type of tensor to a machine learning network.

14. The method as claimed in claim 13, wherein rendering a user interface on the display the menu on the display that displays different types of tensors comprising displaying a selection between a waveform vector, a waveform image, and S-parameter image.

15. The method as claimed in claim 13, further comprising:
receiving a user selection selecting a waveform vector; and
rendering a second user interface having selections to allow the user to define short pattern inputs, bar graph inputs, measured noise, and measurements.

16. The method as claimed in claim 15, wherein building the selected type of tensor from the data from the DUT comprises building a one-dimensional waveform vector of multiple user defined short pattern waveform sequences concatenated together.

17. The method as claimed in claim 13, further comprising:
receiving a user selection selecting a waveform image; and
rendering a second user interface having selections for the user to define short pattern inputs, image builder, bar graph inputs, measured noise, and measurements.

18. The method as claimed in claim 17, wherein building a two-dimensional waveform image comprises building a two-dimensional waveform image from short pattern waveform sequences including histogram data.

19. The method as claimed in claim 13, further comprising:
receiving a user selection selecting a S-parameter image; and
rendering a second user interface having selections for dimensions, image builder, and bar graph inputs.

20. The method as claimed in claim 19, wherein building an S-parameter image comprises building an S-parameter image having rows in an XY image, each row in the XY image representing one of either real or imaginary parts of the S-parameters, or magnitudes and phases of the S-parameters.
